(19) United States
(12) Patent Application Publication
(10) Pub. No.: US 2022/0406803 A1
(43) Pub. Date: Dec. 22, 2022

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventor: Ayumu OZAWA, Nagoya (JP)

(73) Assignee: Kioxia Corporation, Tokyo (JP)

(21) Appl. No.: 17/643,267

(22) Filed: Dec. 8, 2021

(30) Foreign Application Priority Data
Jun. 16, 2021 (JP) 2021-100304

(51) Int. Cl. H01L 27/11551; H01L 27/11565; H01L 27/11519; H01L 27/11578

(52) U.S. Cl. CPC H01L 27/11551; H01L 27/11565; H01L 27/11519; H01L 27/11578

(57) ABSTRACT

A semiconductor memory device according to an embodiment includes a memory cell array and a contact unit. The contact unit connects the memory cell array to a conductive layer and a contact. The contact unit includes a descending unit and an ascending unit. The descending unit includes a plurality of terrace parts descending in a first direction away from the memory cell array. The ascending unit is adjacent to the descending unit in a second direction perpendicular to the first direction. The ascending unit includes a plurality of terrace parts ascending in the first direction. The contact arranged in the terrace part of the descending unit and the contact arranged in the terrace part of the ascending unit are arranged in the second direction.

### CROSS-REFERENCE TO RELATED APPLICATIONS

This application is based upon and claims the benefit of priority from Japanese Patent Application No. 2021-100304, filed on Jun. 16, 2021; the entire contents of which are incorporated herein by reference.

### FIELD

Embodiments described herein relate generally to a semiconductor memory device and a method for manufacturing a semiconductor memory device.

### BACKGROUND

As a semiconductor memory device, a three-dimensional stacked-type non-volatile memory including memory cells structured in a stacked manner is proposed. In the three-dimensional stacked-type non-volatile memory, a contact unit in which word lines are drawn at respective layers of the memory cells arranged in the height direction sometimes employs a staircase structure. For example, proposed is a contact unit having a structure in which a first staircase unit including a plurality of terrace parts descending in a direction away from the memory cells and a second staircase unit including a plurality of terrace parts ascending in the same direction are arranged to be opposed to each other. However, in the conventional structure, there are many terrace parts that cannot be provided with contacts, which makes it difficult to increase the number of contacts to be arranged and reduce the size of the contact unit.

### BRIEF DESCRIPTION OF THE DRAWINGS

FIG. 1 is a perspective view illustrating an example of a configuration of a memory cell array of a semiconductor memory device according to an embodiment;

FIG. 2 is a cross-sectional perspective view illustrating an example of a configuration of a contact unit of the semiconductor memory device according to the embodiment;

FIG. 3 is an upper view illustrating the example of the configuration of the contact unit according to the embodiment;

FIG. 4 is a cross-sectional view along the line IV-IV in FIG. 3 illustrating the example of the configuration of the contact unit according to the embodiment;

FIG. 5 is an upper view illustrating an example of a state of a contact unit WC at a first stage of a method for manufacturing a semiconductor memory device according to the embodiment;

FIG. 6 is a cross-sectional view along the line VI-VI in FIG. 5 illustrating the example of the state of the contact unit WC at the first stage of the method for manufacturing a semiconductor memory device according to the embodiment;

FIG. 7 is an upper view illustrating an example of a state of the contact unit WC at a second stage of the method for manufacturing a semiconductor memory device according to the embodiment;

FIG. 8 is a cross-sectional view along the line VIII-VIII in FIG. 7 illustrating the example of the state of the contact unit WC at the second stage of the method for manufacturing a semiconductor memory device according to the embodiment;

FIG. 9 is an upper view illustrating an example of a state of the contact unit WC at a third stage of the method for manufacturing a semiconductor memory device according to the embodiment;

FIG. 10 is a cross-sectional view along the line X-X in FIG. 9 illustrating the example of the state of the contact unit WC at the third stage of the method for manufacturing a semiconductor memory device according to the embodiment;

FIG. 11 is an upper view illustrating an example of a state of the contact unit WC at a fourth stage of the method for manufacturing a semiconductor memory device according to the embodiment; and

FIG. 12 is a cross-sectional view along the line XII-XII in FIG. 11 illustrating the example of the state of the contact unit WC at the fourth stage of the method for manufacturing a semiconductor memory device according to the embodiment.

### DETAILED DESCRIPTION

According to one embodiment, a semiconductor memory device including a memory cell array and a contact unit is provided. The memory cell array has memory cells arranged three-dimensionally in a stacked body in which a plurality of set layers each including a pair including of a conductive layer and an insulating layer are stacked. The contact unit connects the memory cell array to the conductive layer and a contact. The contact unit includes a descending unit and an ascending unit. The descending unit includes a plurality of terrace parts descending in a first direction away from the memory cell array. The ascending unit is adjacent to the descending unit in a second direction perpendicular to the first direction. The ascending unit includes a plurality of terrace parts ascending in the first direction. The contact arranged in the terrace part of the descending unit and the contact arranged in the terrace part of the ascending unit are arranged in the second direction.

A semiconductor memory device and a method for manufacturing the same according to an embodiment will be described below in detail with reference to the accompanying drawings. Note that the present invention is not limited to the present embodiment. Also, the cross-sectional views and the like of the semiconductor memory device used in the following embodiment are schematic, and a relationship between the thickness of and the width of a layer, a ratio of the thicknesses of respective layers, and the like may differ from actual ones. Also, in the following description, a non-volatile memory having a three-dimensional structure will be given as an example of a semiconductor memory device.

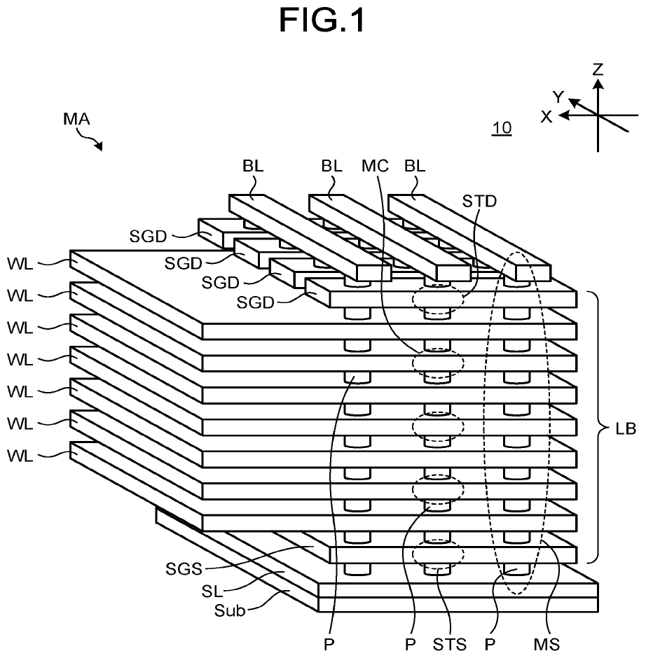

FIG. 1 is a perspective view illustrating an example of a configuration of a memory cell array MA of a semiconductor memory device 10 according to an embodiment. In FIG. 1, two directions parallel to the principal surface of a substrate Sub and perpendicular to each other are referred to as an X direction (an example of a first direction) and a Y direction (an example of a second direction). A direction perpendicular to both the X direction and the Y direction is referred to as a Z direction. On the drawing sheet, a direction from the right to the left is referred to as a positive direction in the X direction, a direction from the front to the rear is referred to as a positive direction in the Y direction, and a direction from the bottom to the top is referred to as a positive direction in the Z direction. Note that, in FIG. 1, interlayer insulating layers and the like are omitted.

As illustrated in FIG. 1, a source line SL serving as a conductive layer is provided on the substrate Sub of the semiconductor memory device 10. The source line SL is provided with a plurality of pillars P made of silicon oxide or the like extending in the Z direction. Each of the pillars P is provided on the side surface thereof with a channel layer made of polysilicon or the like and a memory layer in which a plurality of insulating layers are stacked. For example, the insulating layers have a configuration in which a tunnel insulating film, a charge accumulation film, and a block insulating film are stacked from a side provided with the channel layer. Also, on the source line SL, a stacked body LB, in which a plurality of conductive layers made of tungsten or the like and a plurality of insulating layers made of silicon oxide or the like are alternately stacked via a not-illustrated interlayer insulating layer, is provided. Each of the pillars P penetrates the stacked body LB.

The conductive layer of the stacked body LB in the lowermost layer functions as a source-side select gate line SGS, and the conductive layer in the uppermost layer functions as a drain-side select gate line SGD. The select gate line SGD is divided per set of the pillars P arrayed in the X direction. The plurality of conductive layers interposed between the select gate lines SGS and SGD function as a plurality of word lines WL. That is, the word line WL is an example of “a conductive layer”. The number of word lines WL stacked illustrated in FIG. 1 is illustrative. The insulating layers between the select gate lines SGS and SGD and the plurality of word lines WL function as interlayer insulating layers (not illustrated).

Each of the pillars P is connected to each of bit lines BL on the stacked body LB. Each of the bit lines BL is connected to the plurality of pillars P arrayed in the Y direction.

From the above, memory cells MC arraying in the height direction of the pillars P are arranged at connection portions between the respective pillars P and the word lines WL in the respective layers. A source-side select transistor STS is arranged at a connection portion between each of the pillars P and the select gate line SGS, and a drain-side select transistor STD is arranged at a connection portion between each of the pillars P and the select gate line SGD. The select transistor STS, the plurality of memory cells MC, and the select transistor STD arrayed in the height direction of one pillar P constitute a memory string MS. Also, the memory cells MC arranged three-dimensionally in a matrix form constitute the memory cell array MA.

The select gate lines SGS and SGD and the plurality of word lines WL are drawn out of the memory cell array MA and constitute a contact unit having a staircase structure. In the present example, the contact unit is arranged further on the positive side in the X direction than the memory cell array MA.

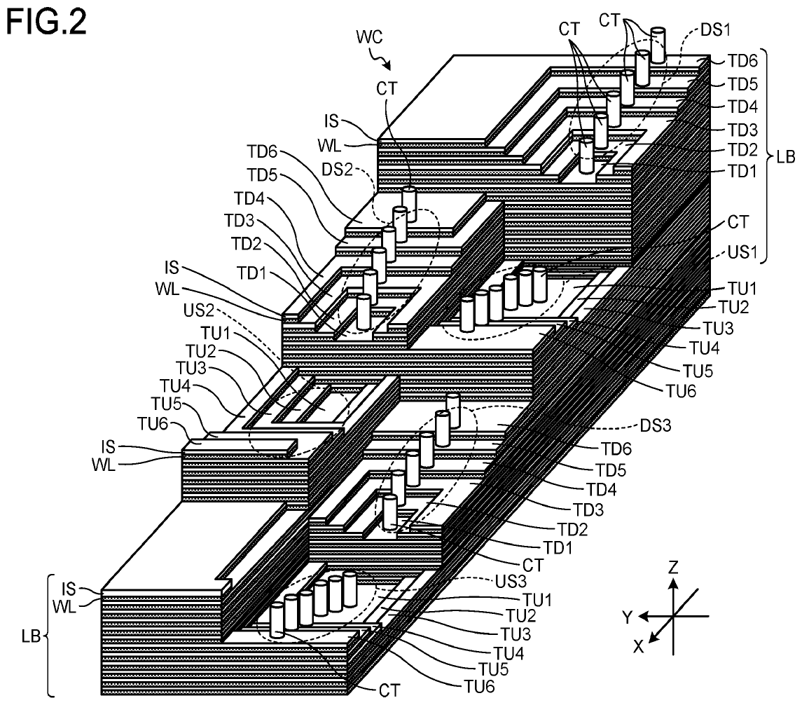

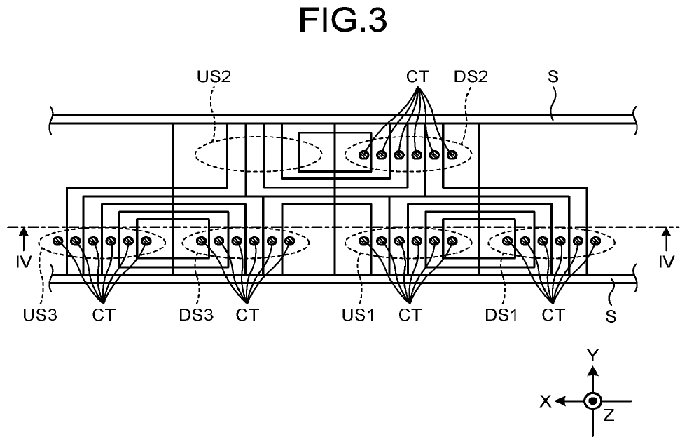

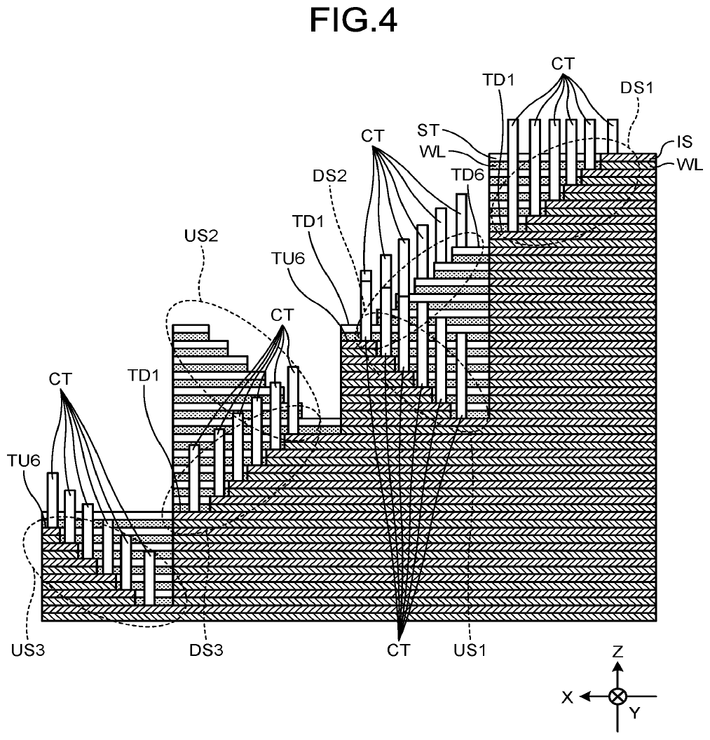

FIG. 2 is a cross-sectional perspective view illustrating an example of a configuration of a contact unit WC of the semiconductor memory device 10 according to the embodiment. FIG. 3 is an upper view illustrating the example of the configuration of the contact unit WC according to the embodiment. FIG. 4 is a cross-sectional view along the line IV-IV in FIG. 3 illustrating the example of the configuration of the contact unit WC according to the embodiment. In FIGS. 2 and 4, the substrate Sub and the like are omitted. Hereinbelow, the word lines WL and the select gate lines SGS and SGD may be referred to as the word lines WL without being distinguished from each other.

The contact unit WC is electrically separated by a plurality of slits S extending in the X direction from contact units adjacent in the Y direction via the slits S. That is, the contact unit WC formed between the two slits S constitutes a single connection set. In FIGS. 2 to 4, a configuration of the contact unit WC corresponding to a single connection set will be described.

The contact unit WC is arranged further outside on the positive side in the X direction than the memory cell array MA and connects the word lines WL to contacts CT in the memory cell array MA. In the contact unit WC according to the present embodiment, the stacked body LB in which a plurality of set layers each including a pair including of the word line WL and an insulating layer IS arranged on the word line WL are stacked in the Z direction has a staircase structure. Each stair of the staircase structure is constituted by the set layer including the pair including of the word line WL and the insulating layer IS.

The staircase structure illustrated here includes three descending units DS1 to DS3 (a first descending unit DS1, a second descending unit DS2, and a third descending unit DS3) and three ascending units US1 to US3 (a first ascending unit US1, a second ascending unit US2, and a third ascending unit US3). Each of the descending units DS1 to DS3 includes a plurality of (six in the present embodiment) terrace parts TD1 to TD6 descending in the X direction. Each of the ascending units US1 to US3 includes a plurality of (six in the present embodiment) terrace parts TU1 to TU6 ascending in the X direction. The terrace parts TD1 to TD6 and TU1 to TU6 are constituted by the insulating layers IS.

As illustrated in FIG. 3, the three descending units DS1 to DS3 are arranged in a staggered form in a top view, and the three ascending units US1 to US3 are arranged in a staggered form in a top view. Therefore, the first descending unit DS1, the first ascending unit US1, the third descending unit DS3, and the third ascending unit US3 are arranged in the X direction. Also, the first ascending unit US1 and the second descending unit DS2 are arranged in the Y direction, and the third descending unit DS3 and the second ascending unit US2 are arranged in the Y direction.

Also, as illustrated in FIG. 4, the terrace part TD1 on the lowermost stair of the first descending unit DS1 is located further on the upper side (upper side in the positive direction in the Z direction) than the terrace part TU6 on the uppermost stair of the first ascending unit US1 adjacent to the first descending unit DS1 in the X direction. Also, the terrace part TD1 on the lowermost stair of the third descending unit DS3 is located further on the upper side than the terrace part TU6 on the uppermost stair of the third ascending unit US3 adjacent to the third descending unit DS3 in the X direction. Also, the terrace part TD6 on the uppermost stair of the second descending unit DS2 is located further on the lower side than the terrace part TD1 on the lowermost stair of the first descending unit DS1, and the terrace part TD1 on the lowermost stair of the second descending unit DS2 is located further on the upper side than the terrace part TU6 on the uppermost stair of the first ascending unit US1.

In the configuration illustrated in FIGS. 2 to 4, six out of the thirty contacts CT are arranged in each of the units including the first descending unit DS1, the second descending unit DS2, the first ascending unit US1, the third descending unit DS3, and the third ascending unit US3. The terrace parts TD1 to TD6 of the first descending unit DS1, the terrace parts TD1 to TD6 of the second descending unit DS2, the terrace parts TU1 to TU6 of the first ascending unit US1, the terrace parts TD1 to TD6 of the third descending unit DS3, and the terrace parts TU1 to TU6 of the third ascending unit US3 are constituted by the insulating layers IS of the different set layers from each other, respectively. The thirty contacts CT are connected to the different word lines WL from each other via contact holes respectively formed in the terrace parts TD1 to TD6 and TU1 to TU6 of the first descending unit DS1, the second descending unit DS2, the first ascending unit US1, the third descending unit DS3, and the third ascending unit US3, respectively. Note that the reason for not arranging the contacts CT in the second ascending unit US2 is that the terrace parts TU1 to TU6 constituting the second ascending unit US2 cannot be constituted by independent set layers.

According to the above configuration, the terrace parts TD1 to TD6 of the first descending unit DS1, the terrace parts TD1 to TD6 of the second descending unit DS2, the terrace parts TU1 to TU6 of the first ascending unit US1, the terrace parts TD1 to TD6 of the third descending unit DS3, and the terrace parts TU1 to TU6 of the third ascending unit US3 can be formed as different layers (set layers each including a pair including of the word line WL and the insulating layer IS), respectively. Consequently, the thirty contacts CT can be connected to the different word lines WL, respectively.

In the present embodiment, as illustrated in FIG. 3, the twenty four contacts CT are arranged in the first descending unit DS1, the first ascending unit US1, the third descending unit DS3, and the third ascending unit US3 in a linear form in the X direction in a top view. Also, in the present embodiment, the six contacts CT respectively arranged in the terrace parts TD1 to TD6 of the second descending unit DS2 and the six contacts CT respectively arranged in the terrace parts TU1 to TU6 of the first ascending unit US1 are arranged in the Y direction. Consequently, the plurality of contacts CT can be arranged in parallel in the X direction.

Note that, although FIGS. 2 to 4 illustrate a configuration in which three descending units and three ascending units are formed in the contact unit WC (formed between the two slits S) constituting a single connection set, and in which each of the descending units and the ascending units includes six terrace parts, the numbers of the descending units, the ascending units, and the terrace parts are not limited to these. For example, four or more descending units and four or more ascending units may be formed in the contact unit WC constituting a single connection set. Also, the number of the terrace parts in each of the descending units and ascending units may be seven or more or five or less.

With the above configuration, the region of the contact unit WC can be utilized efficiently, and many terrace parts that can be provided with the contacts CT can be formed. Accordingly, the number of the contacts CT to be arranged can be increased without increasing the size of the contact unit WC.

A method for manufacturing the contact unit WC described above will be described below.

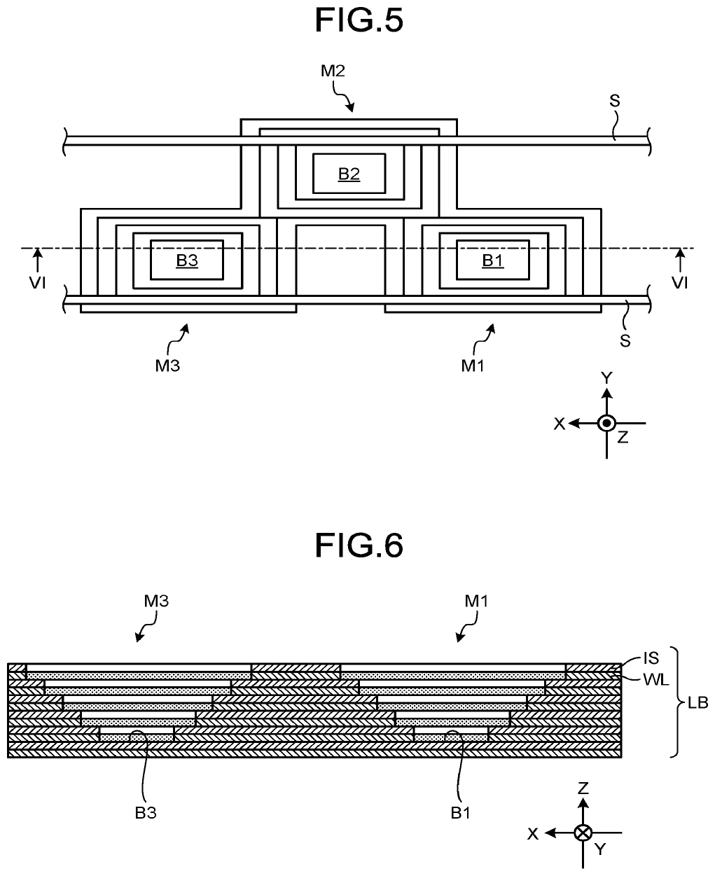

FIG. 5 is an upper view illustrating an example of a state of the contact unit WC at a first stage of a method for manufacturing a semiconductor memory device according to the embodiment. FIG. 6 is a cross-sectional view along the line VI-VI in FIG. 5 illustrating the example of the state of the contact unit WC at the first stage of the method for manufacturing a semiconductor memory device according to the embodiment. In FIG. 6, only the upper six layers of the stacked body LB are illustrated, and a portion of the seventh and lower layers is omitted.

As illustrated in FIG. 5, first, in the stacked body LB constituting the contact unit WC, three conical recesses M1 to M3 (a first recess M1, a second recess M2, and a third recess M3) are formed in a staggered manner in a top view. Although a method for forming the recesses M1 to M3 is not particularly limited, the recesses M1 to M3 each having a predetermined number of (six in the present embodiment) stairs can be formed, for example, by alternately executing etching and slimming. For example, a resist pattern is first formed so that bottoms B1 to B3 respectively corresponding to the recesses M1 to M3 are exposed in a staggered form, and an exposed layer is etched with use of an etching technique such as a reactive ion etching (RIE) method. Subsequently, the resist pattern is slimmed by means of isotropic etching as much as a width corresponding to the terrace part of the staircase structure from the edges of the resist pattern in the X direction and in the Y direction. Etching is performed again using the slimmed resist pattern as a mask, and the resist pattern is further slimmed. By repeating this processing a predetermined number of times, the conical recesses M1 to M3 in which the areas (the lengths of the diagonals) get larger in a staircase pattern from the bottoms B1 to B3 are formed.

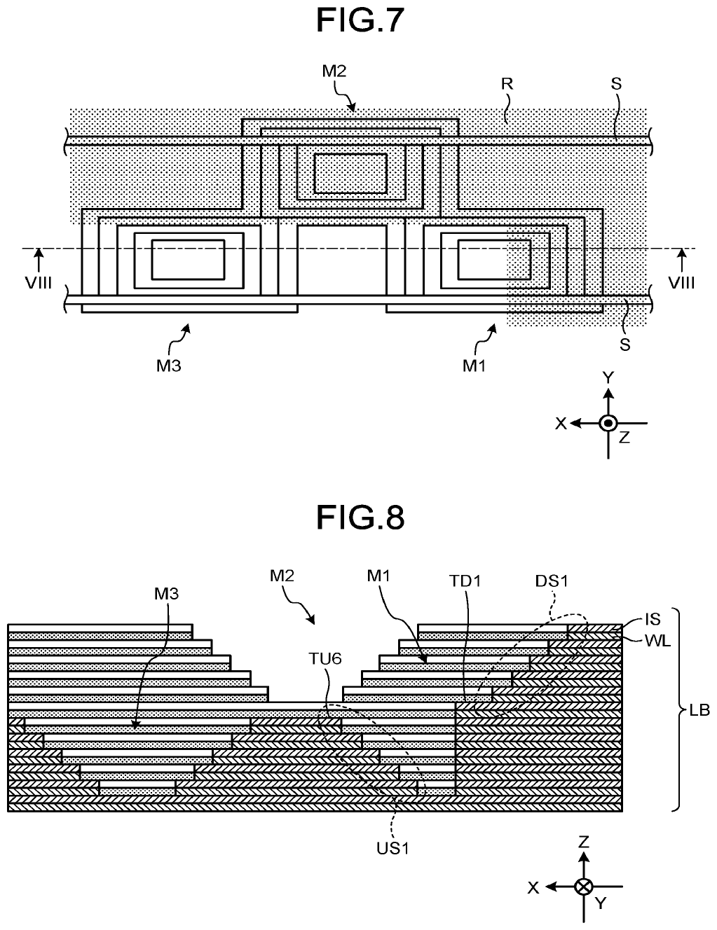

FIG. 7 is an upper view illustrating an example of a state of the contact unit WC at a second stage of the method for manufacturing a semiconductor memory device according to the embodiment. FIG. 8 is a cross-sectional view along the line VIII-VIII in FIG. 7 illustrating the example of the state of the contact unit WC at the second stage of the method for manufacturing a semiconductor memory device according to the embodiment. In FIG. 8, only the upper twelve layers of the stacked body LB are illustrated, and a portion of the thirteenth and lower layers is omitted.

At the second stage, as illustrated in FIG. 7, a resist pattern R is formed to cover the half of the first recess M1 on the negative side in the X direction (a side closer to the memory cell array MA) and the entirety of the second recess M2. By performing etching in this state, as illustrated in FIG. 8, the half of the first recess M1 on the positive side in the X direction (a side farther from the memory cell array MA) and the entirety of the third recess M3 move downward (the negative side in the Z direction). As a result, the first recess M1 is separated in the up-down direction to form the first descending unit DS1 and the first ascending unit US1. At this time, the terrace part TD1 on the lowermost stair of the first descending unit DS1 is located by one layer further on the upper side than the terrace part TU6 on the uppermost stair of the first ascending unit US1.

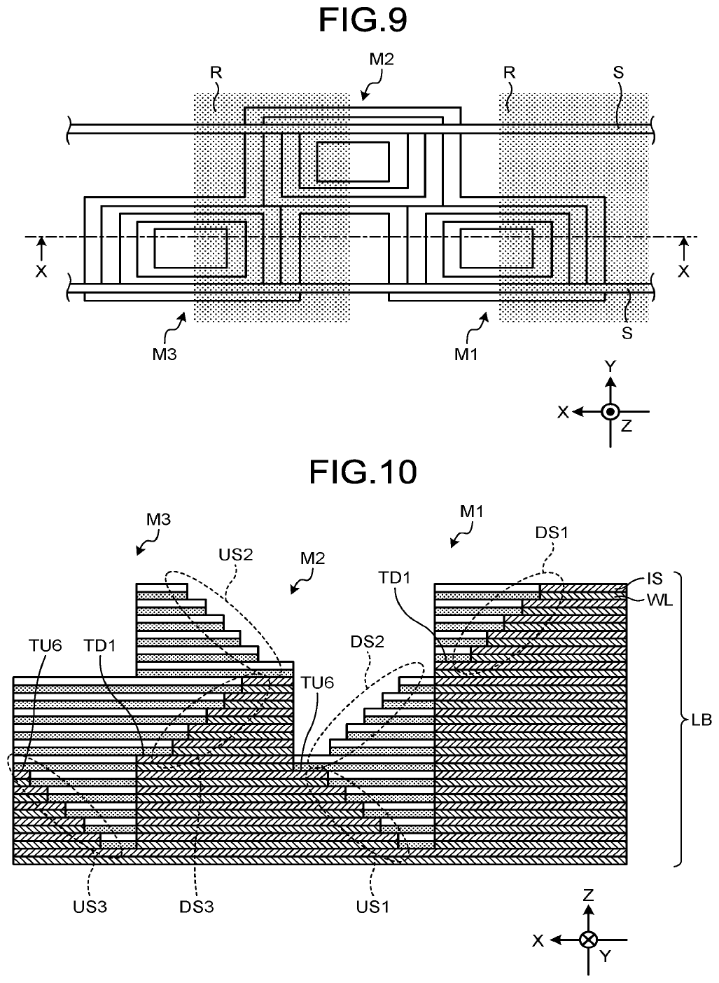

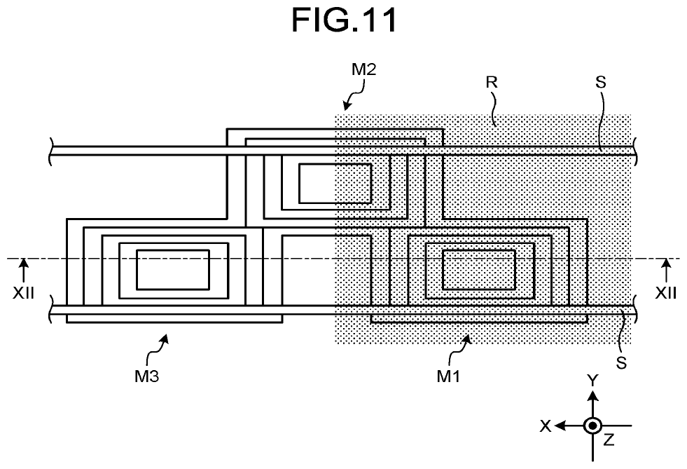

FIG. 9 is an upper view illustrating an example of a state of the contact unit WC at a third stage of the method for manufacturing a semiconductor memory device according to the embodiment. FIG. 10 is a cross-sectional view along the line X-X in FIG. 9 illustrating the example of the state of the contact unit WC at the third stage of the method for manufacturing a semiconductor memory device according to the embodiment. In FIG. 10, only the upper eighteen layers of the stacked body LB are illustrated, and a portion of the nineteenth and lower layers is omitted.

At the third stage, as illustrated in FIG. 9, a resist pattern R is formed to cover the half of the first recess M1 on the negative side in the X direction, the half of the second recess M2 on the positive side in the X direction, and the half of the third recess M3 on the negative side in the X direction. By performing etching in this state, as illustrated in FIG. 10, the half of the first recess M1 on the positive side in the X direction, the half of the second recess M2 on the negative side in the X direction, and the half of the third recess M3 on the positive side in the X direction move downward. As a result, the second recess M2 is separated in the up-down direction to form the second descending unit DS2 and the second ascending unit US2. Also, the third recess M3 is separated in the up-down direction to form the third descending unit DS3 and the third ascending unit US3. At this time, the terrace part TD1 on the lowermost stair of the first descending unit DS1 is located by seven layers further on the upper side than the terrace part TU6 on the uppermost stair of the first ascending unit US1. Also, the terrace part TD1 on the lowermost stair of the third descending unit DS3 is located by one layer further on the upper side than the terrace part TU6 on the uppermost stair of the third ascending unit US3.

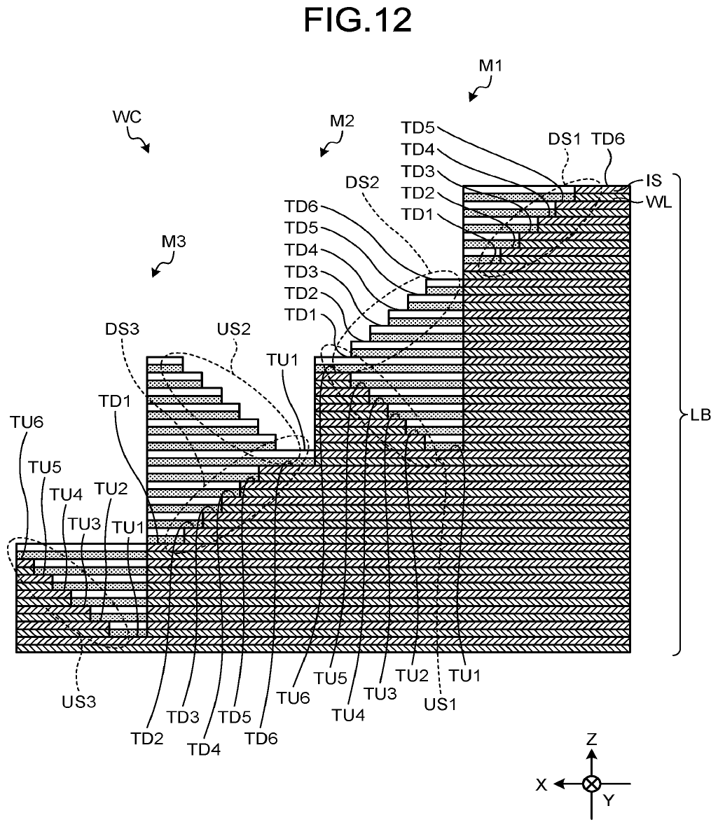

FIG. 11 is an upper view illustrating an example of a state of the contact unit WC at a fourth stage of the method for manufacturing a semiconductor memory device according to the embodiment. FIG. 12 is a cross-sectional view along the line XII-XII in FIG. 11 illustrating the example of the state of the contact unit WC at the fourth stage of the method for manufacturing a semiconductor memory device according to the embodiment. In FIG. 12, all the thirty layers of the stacked body LB according to the present embodiment are illustrated.

At the fourth stage, as illustrated in FIG. 11, a resist pattern R is formed to cover the entirety of the first recess M1 and the half of the second recess M2 on the negative side in the X direction. By performing etching in this state, as illustrated in FIG. 12, the half of the second recess M2 on the positive side in the X direction and the entirety of the third recess M3 move downward. At this time, the terrace part TD6 on the uppermost stair of the second descending unit DS2 is located by one layer further on the lower side than the terrace part TD1 on the lowermost stair of the first descending unit DS1, and the terrace part TD1 on the lowermost stair of the second descending unit DS2 is located by one layer further on the upper side than the terrace part TU6 on the uppermost stair of the first ascending unit US1. The other part is in a similar state to the state at the third stage illustrated in FIG. 10.

With the manufacturing method described above, it is possible to manufacture a semiconductor memory device including the contact unit WC that has a compact configuration and that can be provided with many contacts CT.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array that has memory cells arranged three-dimensionally in a stacked body in which a plurality of set layers each including a pair including of a conductive layer and an insulating layer are stacked; and
at least one contact unit that connects the conductive layer to a contact,
wherein the contact unit includes at least one descending unit including a plurality of terrace parts descending in a first direction away from the memory cell array and at least one ascending unit adjacent to the descending unit in a second direction perpendicular to the first direction,
the ascending unit includes a plurality of terrace parts ascending in the first direction, and
the contact arranged in the terrace part of the descending unit and the contact arranged in the terrace part of the ascending unit are arranged in the second direction.

2. The semiconductor memory device according to claim 1,
wherein the plurality of descending units are arranged in a staggered form in a top view, and
the plurality of ascending units are arranged in a staggered form in a top view.

3. The semiconductor memory device according to claim 2,
wherein the terrace part on a lowermost stair of the descending unit is located further on an upper side than the terrace part on an uppermost stair of the ascending unit adjacent to the descending unit in the first direction.

4. The semiconductor memory device according to claim 2,
wherein the terrace part on the lowermost stair of first descending unit is located further on an upper side than the terrace part on an uppermost stair of second descending unit arranged at a position farther from the memory cell array than the first descending unit.

5. The semiconductor memory device according to claim 2,
wherein the terrace part on the lowermost stair of the descending unit is located further on an upper side than the terrace part on an uppermost stair of the ascending unit adjacent to the descending unit in the second direction.

6. The semiconductor memory device according to claim 1, comprising:
the plurality of contact units,
wherein the two contact units adjacent in the second direction are electrically separated by at least one slit extending in the first direction.

7. The semiconductor memory device according to claim 6,
wherein the contact unit formed between the two slits includes the three or more descending units and the three or more ascending units.

8. The semiconductor memory device according to claim 7,
wherein each of the descending units includes the six or more terrace parts, and
each of the ascending units includes the six or more terrace parts.

9. The semiconductor memory device according to claim 1,
wherein the contact unit includes the ascending unit in which the contact is not arranged.

10. The semiconductor memory device according to claim 1,
wherein the conductive layer in a lowermost layer of the stacked body functions as a source-side select gate line, and
the conductive layer in an uppermost layer of the stacked body functions as a drain-side select gate line.

11. A method for manufacturing a semiconductor memory device, the semiconductor memory device including a memory cell array that has memory cells arranged three-dimensionally in a stacked body in which a plurality of set layers each including a pair including of a conductive layer and an insulating layer are stacked and at least one contact unit that connects the conductive layer to a contact, the method comprising:
forming in the contact unit a plurality of recesses each formed in a conical shape in a staggered manner in a top view;
dividing each of the plurality of recesses into two in a first direction away from the memory cell array to form at least one descending unit including a plurality of terrace parts descending in the first direction and at least one ascending unit including a plurality of terrace parts ascending in the first direction and adjacent to the descending unit in a second direction perpendicular to the first direction; and
arranging the contact arranged in the terrace part of the descending unit and the contact arranged in the terrace part of the ascending unit in the second direction.

12. The method for manufacturing a semiconductor memory device according to claim 11, comprising:
arranging the plurality of descending units in a staggered form in a top view; and
arranging the plurality of ascending units in a staggered form in a top view.

13. The method for manufacturing a semiconductor memory device according to claim 12, comprising:
locating the terrace part on a lowermost stair of the descending unit further on an upper side than the terrace part on an uppermost stair of the ascending unit adjacent to the descending unit in the first direction.

14. The method for manufacturing a semiconductor memory device according to claim 12, comprising:
locating the terrace part on the lowermost stair of first descending unit further on an upper side than the terrace part on an uppermost stair of second descending unit arranged at a position farther from the memory cell array than the first descending unit.

15. The method for manufacturing a semiconductor memory device according to claim 12, comprising:
locating the terrace part on the lowermost stair of the descending unit further on an upper side than the terrace part on an uppermost stair of the ascending unit adjacent to the descending unit in the second direction.

16. The method for manufacturing a semiconductor memory device according to claim 11, comprising:
forming the plurality of contact units electrically separated by at least one slit extending in the first direction and adjacent in the second direction.

17. The method for manufacturing a semiconductor memory device according to claim 16, comprising:
forming in the contact unit formed between the two slits the three or more descending units and the three or more ascending units.

18. The method for manufacturing a semiconductor memory device according to claim 17, comprising:
forming in each of the descending units the six or more terrace parts; and
forming in each of the ascending units the six or more terrace parts.

19. The method for manufacturing a semiconductor memory device according to claim 11, comprising:
forming in the contact unit the ascending unit in which the contact is not arranged.

20. The method for manufacturing a semiconductor memory device according to claim 11, comprising:
forming the conductive layer in a lowermost layer of the stacked body as a source-side select gate line; and
forming the conductive layer in an uppermost layer of the stacked body as a drain-side select gate line.
